(19) United States
(12) Patent Application Publication
(10) Pub. No.: US 2009/0001359 A1
(43) Pub. Date: Jan. 1, 2009

(54) Redox Systems for Stabilization and Life Extension of Polymer Semiconductors

(75) Inventors: Jasmin Worle, Furth (DE); Andreas Ullmann, Zirndorf (DE); Henning Rost, Erlangen (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(73) Assignee: POLYIC GMBH & CO. KG, Furth (DE)

(21) Appl. No.: 12/096,687

(22) PCT Filed: Dec. 11, 2006
(86) PCT No.: PCT/EP2006/011899

§ 371 Date: Jun. 26, 2008

(30) Foreign Application Priority Data
Dec. 12, 2005 (DE) 10 2005 059 608.8

(51) Int. Cl. H01L 51/30

(52) U.S. Cl. 257/40; 257/E51.024

(57) ABSTRACT

The invention relates to an organic electronic component with improved voltage stability and a method for producing it, wherein the voltage stability in the device is improved by targeted addition of additives and/or by formation of an interlayer. The invention for the first time makes it possible to stabilize organic electronic components by modification with a reducing, oxidizing and/or redox system comprising one and/or more functional materials and/or by incorporation of one or more interlayers comprising, as main constituent, a reducing, oxidizing and/or redox system, primarily in the area of relatively high voltages.

The invention relates to an organic electronic component with improved voltage stability and a method for producing it, wherein the voltage stability in the device is improved by targeted addition of additives and/or by formation of interlayers.

Organic electronic components are known not just in the form of the most widely developed organic light emitting diodes OLEDs, rather in the form of field effect transistors (OFETs), diodes, capacitors and photocells, too, organic electronics have for a long time gained a foothold in research and development. By way of example, both an organic field effect transistor and an organic rectifier are known from DE 10033112 and DE 100 44 842.

What is disadvantageous about the known organic electronic components is that the functional materials used for the construction of the components have only a limited stability at relatively high voltages, due to the electrochemical degradation of the materials in the electric field.

Therefore, it is an object of the present invention to provide a functional material for an organic electronic component which ensures a high stability even at relatively high voltages.

The invention relates to an organic electronic component, comprising at least one substrate, a bottom electrode layer, a top electrode layer and in between at least one layer composed of an organic functional material, wherein at least one layer contains a reducing, oxidizing and/or redox system as additive or as main constituent.

The organic electronic component can be all types of previously known or future components which comprise a functional layer composed of organic material, wherein the functionality of the functional layer is instigated by applying or generating a voltage.

In particular, what are appropriate in this case are organic electronic components such as thin film transistors (TFTs), field effect transistors (OFETs), organic photosensitive components, rectifiers, data memories, sensors, optocouplers, displays, solar cells and/or similar components on an organic basis—this implies all materials which have been published in the last 10-15 years under a wide variety of designations such as polymer semiconductors, inorganic/organic electronics, small molecules, as well as the materials that will newly come out in the future for these fields of application.

In this case, various materials are used as the substrate; it is possible to use glasses, in particular extremely thin glasses, quartz, films, thin films, inter alia. The reducing, oxidizing and/or redox system according to the invention can also or only be contained in the substrate.

The bottom/top electrode layer of the component can likewise vary; it can be metallic and/or composed of organic and/or organic-inorganic hybrid material, wherein the reducing, oxidizing and/or redox system according to one preferred embodiment of the invention can also or only be contained in one of the two and/or in both electrode layers and/or as an interlayer between the electrode layer and an adjoining layer.

According to one preferred embodiment, the reducing, oxidizing and/or redox system is contained in the organic functional layer arranged between the two electrode layers as an additive or in the form of an adjoining interlayer.

According to a further preferred embodiment, the reducing, oxidizing and/or redox system is contained in an insulating interlayer of the organic component as an additive or as an adjoining interlayer.

The reducing, oxidizing and/or redox system is contained as an additive for example when it is added as an additive to a material, which can in turn be processed from solution, for example, in an amount of 1 to 50% by weight and in particular preferably of 1 to 25% by weight.

The reducing, oxidizing and/or redox system is the main constituent of a layer if it can be processed as an interlayer for example in solution and is contained with a layer thickness of approximately 1 nm to 1 μm as an interlayer in the organic electronic component.

Firstly all known reducing, oxidizing and/or redox systems that are miscible and/or stable in connection with the other materials, that is to say chemical compounds which can both take up and emit electrons, are appropriate as reducing, oxidizing and/or redox system. In contrast to the interlayers which have usually been used hitherto and which act in either hole- or electron-stabilizing fashion, that is to say can be used as buffers for holes or electrons, the introduction of a redox system, for example, has a stabilizing effect on both charge carriers, holes as well as electrons.

The advantage of electrochemically stable redox systems is also that they absorb excess charge carriers formed in the electric field and primarily at high voltages, and therefore protect these materials against irreversible degradation.

Preferred redox systems are organometallic π complexes, for example, in which, on the one hand, an interaction of the π electrons of the organic ligands with the unoccupied metal valence orbitals takes place and, on the other hand, an acceptor bond can transfer the charge from the filled metal d-orbitals into unoccupied ligand orbitals. These systems have many possibilities of stabilizing additional positive or negative charges and are miscible with organic materials without any problems, owing to their large organic ligands. Examples of such systems are all substituted and unsubstituted metallocenes, which have already been used successfully here. A classic representative of the metallocenes is ferrocene, which is commercially available at low cost.

A further group of redox systems is formed by the group of quinones and hydroquinones and the derivatives thereof. These redox systems are also very stable and readily miscible with other organic materials. In this case, too, charges can be stabilized well by means of the aromatic structure with the two electronegative elements in parallel position. This functionality of the quinones can also be reinforced, under certain circumstances, by aromatic systems having a higher degree of condensation.

Further possible redox systems are for example Lewis acids and bases.

The invention will be explained in more detail below on the basis of exemplary embodiments:

### EXAMPLE 1

### Modification of the Semiconductor Material in an Organic Electronic Diode:

In order to prepare the semiconductor solution, 70-90% by weight of polymeric solid (polythiophene, PAT) are mixed with 10-30% by weight of a hydroquinone derivative and brought to solution. The diodes are then processed by a standard process. (Electrodes: Au/Cu; semiconductor: polythiophene; diodes on PET film)

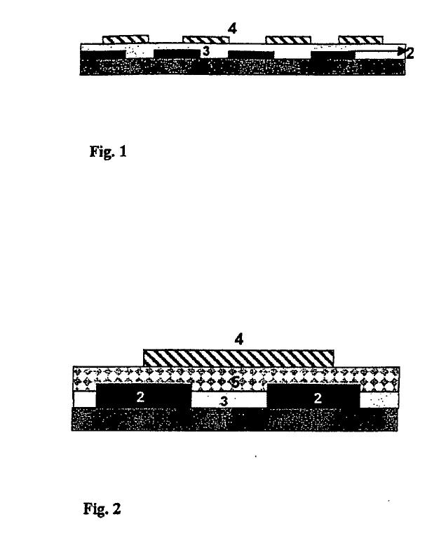

A layer construction as shown in FIG. 1 is realized in this case:

The bottommost layer 1 is the substrate layer, on which lies the bottom electrode layer 2, for example composed of a metal and/or an alloy such as a gold alloy or gold, and on that is the semiconducting layer 3 composed of polythiophene with a reducing, oxidizing and/or redox additive, followed by the top electrode layer 4, once again composed of a metal or an alloy, for example composed of copper.

### EXAMPLE 2

### Modification of the Semiconductor Material in an Organic Field Effect Transistor:

In order to prepare the semiconductor solution, 70-90% by weight of solid (polythiophene, PAT) are mixed with 10-30% by weight of a hydroquinone derivative and brought to solution. The transistors are once again processed by a standard process.

The layer construction is shown in FIG. 2: At the bottom the substrate layer 1, for example composed of a PET film, with the adjoining bottom electrode layer 2, for example composed of metal and/or an alloy, such as a gold alloy, or pure gold; this layer is surrounded firstly by the semiconducting layer 3, which comprises the modified material as described above, and adjoining that the insulating layer 5, followed by the top electrode layer 4, once again composed of a metal or an alloy, for example composed of copper.

### EXAMPLE 3

Modification of Other Functional Layers Apart from the Semiconductor Layer and/or the Substrate Material for Application in Organic Electronic Components.

In order to stabilize the functional layers for application in organic electronic components and/or for matching the respective energy levels to one another, it is also possible to modify the insulator material, for example PMMA, or the substrate material, for example PET, with the reducing, oxidizing or redox system.

Furthermore, there is the possibility, when using polymeric electrode layers, for example composed of PEDOT or PANI, of stabilizing one or both electrode materials supplementarily or solely likewise with the reducing, oxidizing and/or redox system.

### EXAMPLE 4

Furthermore, alternatively or supplementarily to the modification of one or more materials, the reducing, oxidizing and/or redox systems can also be introduced as interlayers into the organic electronic component. In this case, the term interlayers preferably denotes layers which lie between functional layers of the organic electronic component.

By way of example, the following interlayers can be introduced as shown by way of example in FIGS. 3 to 7.

FIG. 3 shows a construction for a transistor such as the one from FIG. 2, wherein an interlayer 6 composed of a reducing, oxidizing and/or redox system is arranged between the substrate 1 and the semiconducting layer 3.

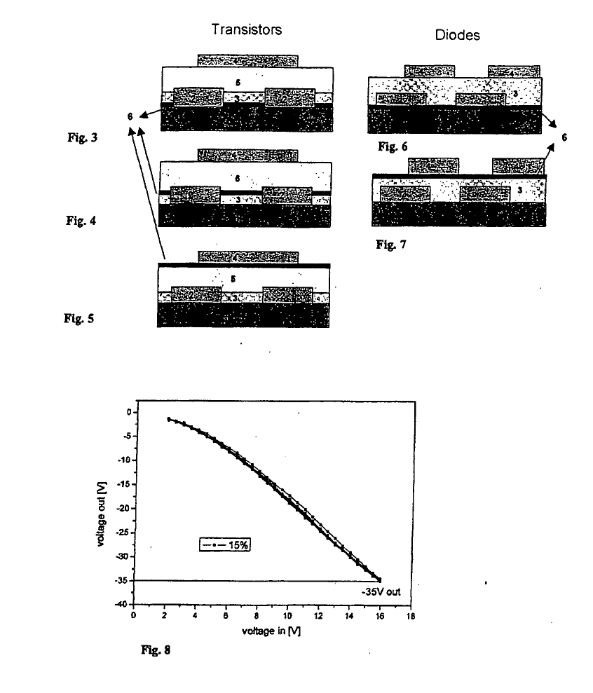

FIG. 4 shows a construction similar to FIG. 3 with the difference that here the interlayer 6 is arranged between the semiconducting layer and the insulating layer.

FIG. 5, finally, again shows the construction similar to FIG. 3 or FIG. 4, wherein the interlayer 6 this time is arranged between the insulator layer 5 and the top electrode layer 4.

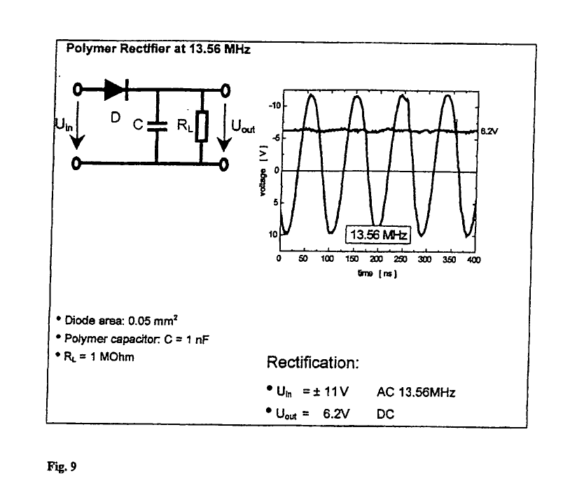

FIGS. 6 and 7 show the possible arrangement of interlayers in organic electronic diodes:

FIG. 6 shows the arrangement of the interlayer 6 in a diode such as is known from FIG. 1, between the substrate 1 and the semiconducting layer 3.

FIG. 7, finally, shows in a similar diode construction the arrangement of the interlayer 6 between the semiconducting layer 3 and the top electrode layer 4.

Although only the modification of a layer material or the incorporation of an interlayer composed of a reducing, oxidizing and/or redox system has been described and shown throughout the figures and the examples, it is nevertheless an essential aspect of the invention that the addition of a reducing, oxidizing and/or redox system to a material and/or the incorporation of an interlayer containing a reducing, oxidizing and/or redox system can be combined as desired. A plurality of interlayers composed of a plurality of reducing, oxidizing and/or redox systems and/or a plurality of material layers modified with possibly different reducing, oxidizing and/or redox systems can be present alongside one another in the organic electronic component.

FIGS. 8 and 9 show the measurement results obtained with diodes produced from modified semiconductor material, in that case composed of PHT mixed with 10-30% of a hydroquinone derivative.

The stabilization of the diode in a Villard rectifier with an input voltage of up to 16 V over a plurality of cycles can be discerned very clearly here.

The results of such a diode which was incorporated into a polymeric simple rectifier can be seen in FIG. 9.

The invention for the first time makes it possible to stabilize organic electronic components by modification with a reducing, oxidizing and/or redox system comprising one or more functional materials and/or by incorporation of one or more interlayers comprising, as main constituent, a reducing, oxidizing and/or redox system, primarily in the area of relatively high voltages.

1. An organic electronic component, comprising
at least one substrate layer;
a bottom electrode layer on the substrate layer;
a top electrode layer on the substrate layer; and
between the bottom and the top electrode layers, at least one layer composed of an organic functional material, wherein at least one of said layers contains an electrochemically stable compound as an additive or as a main constituent, which compound is from at least one of the class of quinones/hydroquinones or from the class of organometallic π-complexes including metallocenes.

2. The component as claimed in claim 1, wherein the at least one organic functional layer comprises at least one of a semiconductor layer and an insulating layer, wherein the compound from the class of quinones/hydro-quinones and/or the compound from the class of organometallic π-complexes including metallocenes is in an interlayer between one of the electrode layers and the insulating or semiconducting functional layer.

3. A method for producing an organic electronic component, in which a bottom and a top electrode layer and in between at least one organic functional layer are on a substrate layer, wherein a compound from the class of quinones/hydroquinones and/or a compound from the class of organometallic π-complexes including metallocenes, is added to at least one of the layers as an additive for modifying the layer material and/or at least one additional interlayer is formed from a material comprising a compound from the class of quinones/hydroquinones and/or a compound from the class of organometallic π-complexes, in particular the metallocenes.
